(19) United States
(12) Patent Application Publication
(10) Pub. No.: US 2025/0149403 A1
(43) Pub. Date: May 8, 2025

(54) COOLING SYSTEM FOR HETEROGENEOUS INTEGRATED SEMICONDUCTOR PACKAGE STRUCTURE

(71) Applicant: Wistron Corporation, New Taipei City (TW)

(72) Inventors: Tung-Yang TANG, New Taipei City (TW); Chu-Shun CHO, New Taipei City (TW); Wen-Hua LIU, New Taipei City (TW); Chu-Chia TSAI, New Taipei City (TW)

(21) Appl. No.: 18/425,211

(22) Filed: Jan. 29, 2024

(30) Foreign Application Priority Data
Nov. 2, 2023 (TW) 112142317

(51) Int. Cl. H01L 23/427; H01L 25/065; H01L 25/10

(52) U.S. Cl. CPC H01L 23/427; H01L 25/0655; H01L 25/105

(57) ABSTRACT

A cooling system for a heterogeneous integrated semiconductor package structure is disclosed. The heterogeneous integrated semiconductor package structure is arranged on a circuit board. The cooling system may include a cooling component. The cooling component may be arranged on the heterogeneous integrated semiconductor package structure, and is configured to dissipate heat from the heterogeneous integrated semiconductor package structure by using a cooling fluid.

### CROSS-REFERENCE TO RELATED APPLICATION

This non-provisional application claims priority under 35 U.S.C. § 119 (a) to patent application No. 112142317 filed in Taiwan, R.O.C. on Nov. 2, 2023, the entire contents of which are hereby incorporated by reference.

### BACKGROUND

### Technical Field

The present disclosure relates to a cooling system, and in particular, to a cooling system configured to cool a chip in a package structure having a plurality of heat sources.

### Related Art

As the era of artificial intelligence (AI) with a high computing capability comes, demands for high-performance computing (HPC) and high-frequency high-speed transmission are growing with each passing day. In response to this, a heterogeneous integrated package structure and a silicon photonics package structure gradually emerge.

As human demands for a computing capability and a transmission rate grow exponentially, power consumption of a server continuously increases, but a cooling technology is upgraded. Since a current heat dissipation capacity of air cooling is inadequate, a direct liquid cooling technology emerges. Existing liquid cooling technologies include immersion, a cooling plate (cold plate), a microchannel, jet impingement, and the like.

In addition, although the liquid cooling technologies provide a high heat dissipation capacity, and related technologies have long been developed, the liquid cooling technologies have not been brought into mass production till today. A main reason is that the air cooling technology can still cope with thermal power consumption of an existing computing system with the heat dissipation capacity. In addition, the liquid cooling technology still has a potential risk of liquid leakage, which may cause a failure to electronic components. Therefore, relevant manufacturers are relatively conservative and cautious when introducing the liquid cooling technology.

### SUMMARY

In view of the above, embodiments of the present disclosure provide a cooling system for a heterogeneous integrated semiconductor package structure, which dissipates heat from the semiconductor package structure by using a cooling fluid. In this way, not only are shortcomings of the related art overcome, but also a heat dissipation requirement of a high computing capability and high-speed transmission is further satisfied.

An embodiment of the present disclosure provides a cooling system for a heterogeneous integrated semiconductor package structure. The heterogeneous integrated semiconductor package structure is arranged on a circuit board. The cooling system may include a cooling component arranged on the heterogeneous integrated semiconductor package structure.

In some embodiments, the cooling system may further include a thermally conductive fastener and a heat dissipation plate. The heat dissipation plate may be arranged on a side of the circuit board opposite to the heterogeneous integrated semiconductor package structure. The thermally conductive fastener may be configured to be coupled to the cooling component and the heat dissipation plate.

In some embodiments, the cooling system may further include a stiffener that may be arranged on the circuit board. The thermally conductive fastener may be configured to be coupled to the cooling component, the stiffener, and the heat dissipation plate.

In some embodiments, the cooling system may further include a reinforcing frame. The reinforcing frame may be arranged on the circuit board and is in contact with the cooling component.

In some embodiments, the cooling component may include a vapor chamber.

In some embodiments, the cooling system may further include a cooling fluid driving module. The reinforcing frame may include a cooling fluid passage that may be in communication with the cooling fluid driving module. The cooling fluid driving module is adapted to supply a cooling fluid to the cooling fluid passage.

In some embodiments, the cooling system may further include a flow path component that may be arranged on a side of the circuit board opposite to the heterogeneous integrated semiconductor package structure. The flow path component may be coupled to the cooling component, and may include a plurality of fluid channels. The cooling component may include an internal chamber. The fluid channels may be in communication with the internal chamber.

In some embodiments, the cooling system may further include a plurality of oxygen-free copper seal components that may be arranged at a coupling position between the flow path component and the cooling component.

In some embodiments, the heterogeneous integrated semiconductor package structure may include a first heat-generating portion and a second heat-generating portion. A thermal design power (TDP) of the first heat-generating portion is greater than a thermal design power of the second heat-generating portion. The cooling component may include a plurality of fluid supply holes corresponding to the heterogeneous integrated semiconductor package structure. A flow rate of a cooling fluid sprayed onto the first heat-generating portion through the fluid supply holes is higher than a flow rate of a cooling fluid sprayed onto the second heat-generating portion through the fluid supply holes.

In some embodiments, the cooling component may further include a main fluid chamber, a fluid supply chamber, a fluid recovery chamber, and a plurality of fluid recovery holes. The fluid supply holes may be configured to be in communication with the main fluid chamber and the fluid supply chamber. The fluid recovery holes may be configured to be in communication with the main fluid chamber and the fluid recovery chamber. A configuration density of the fluid supply holes corresponding to the first heat-generating portion is greater than a configuration density of the fluid supply holes corresponding to the second heat-generating portion.

In some embodiments, the cooling system may further include a fluid supply module. The heterogeneous integrated semiconductor package structure may include a first heat-generating portion and a second heat-generating portion, and a thermal design power of the first heat-generating portion is greater than a thermal design power of the second heat-generating portion. The cooling component may include a first fluid chamber and a second fluid chamber. The first fluid chamber may correspond to the first heat-generating portion. The second fluid chamber may correspond to the second heat-generating portion. The fluid supply module is adapted to supply a cooling fluid to the first fluid chamber and the second fluid chamber. A flow rate of the cooling fluid supplied to the first fluid chamber by the fluid supply module is greater than a flow rate of the cooling fluid supplied to the second fluid chamber.

In some embodiments, the fluid supply module may include a fluid supply pump, a fluid distribution valve, a first inlet pipe, and a second inlet pipe. Two ends of the first inlet pipe may be respectively in communication with the fluid distribution valve and the first fluid chamber. Two ends of the second inlet pipe may be respectively in communication with the fluid distribution valve and the second fluid chamber. The fluid supply pump is adapted to supply the cooling fluid to the fluid distribution valve. The fluid distribution valve may be configured to cause a flow rate of the cooling fluid supplied to the first inlet pipe to be greater than a flow rate of the cooling fluid supplied to the second inlet pipe.

In some embodiments, the fluid supply module may include a first fluid supply pump and a second fluid supply pump. The first fluid supply pump is adapted to supply the cooling fluid to the first fluid chamber. The second fluid supply pump is adapted to supply the cooling fluid to the second fluid chamber. A flow rate of the cooling fluid supplied to the first fluid chamber by the first fluid supply pump is greater than a flow rate of the cooling fluid supplied to the second fluid chamber by the second fluid supply pump.

In some embodiments, the fluid supply module may include a fluid supply pump, a first inlet pipe, and a second inlet pipe. Two ends of the first inlet pipe may be respectively in communication with the fluid supply pump and the first fluid chamber. Two ends of the second inlet pipe may be respectively in communication with the fluid supply pump and the second fluid chamber. The fluid supply pump is adapted to supply the cooling fluid to the first fluid chamber and the second fluid chamber respectively through the first inlet pipe and the second inlet pipe. A pipe diameter of the first inlet pipe is greater than a pipe diameter of the second inlet pipe.

In some embodiments, the fluid supply module may include a fluid supply pump, a first inlet pipe, and a second inlet pipe. Two ends of the first inlet pipe may be respectively in communication with the fluid supply pump and an inlet hole of the first fluid chamber. Two ends of the second inlet pipe may be respectively in communication with the fluid supply pump and an inlet hole of the second fluid chamber. The fluid supply pump is adapted to supply the cooling fluid to the first fluid chamber and the second fluid chamber respectively through the first inlet pipe and the second inlet pipe. An orifice diameter of the inlet hole of the first fluid chamber is greater than an orifice diameter of the inlet hole of the second fluid chamber.

In some embodiments, the cooling system may further include a fluid supply module and a fluid recovery module. The cooling component includes a cooling chamber and a recovery chamber. The cooling chamber and the recovery chamber may be in communication with each other. The fluid supply module may be in communication with the cooling chamber and is adapted to supply a cooling fluid to the cooling chamber. The fluid recovery module may be in communication with the recovery chamber, and may include a gas recovery pump. The gas recovery pump is adapted to draw the evaporated cooling fluid from the recovery chamber.

In some embodiments, the cooling system may further include a fluid storage unit, a fluid supply pipeline, a fluid recovery pipeline, a first fluid pump, and a second fluid pump. The cooling component may include a hollow chamber. The fluid storage unit may store a cooling fluid. Two ends of each of the fluid supply pipeline and the fluid recovery pipeline may be respectively in communication with the fluid storage unit and the hollow chamber of the cooling component. The first fluid pump may be arranged on the fluid supply pipeline. The second fluid pump may be arranged on the fluid recovery pipeline. The cooling fluid is supplied to the cooling component by the first fluid pump through the fluid supply pipeline, or the cooling fluid is supplied to the cooling component by the second fluid pump through the fluid recovery pipeline.

In some embodiments, the cooling system may further include a controller, a sensor, and a fluid driving unit. The fluid driving unit is adapted to supply a cooling fluid to the cooling component. The controller may be arranged on the circuit board, and may be electrically connected to the sensor and the fluid driving unit. The controller is adapted to control the fluid driving unit to supply the cooling fluid to the cooling component based on a sensing result of the sensor.

In some embodiments, the cooling component may include a plurality of first fluid channels and a plurality of second fluid channels. The first fluid channels and the second fluid channels may be arranged to be spaced apart from each other in the cooling component in a substantially parallel and staggered manner. Flowing directions of cooling fluids in the first fluid channel and the second fluid channel adjacent to each other may be opposite to each other.

In some embodiments, the cooling component may include a flow channel. An inner surface of the flow channel may be coated with a diamond-like film.

The summary presented above does not include an exhaustive list of all aspects of the instant disclosure. It is provided merely to introduce certain concepts and not to identify any key or essential features of the claimed subject matters.

### BRIEF DESCRIPTION OF THE DRAWINGS

FIG. 1A is a schematic cross-sectional view showing a cooling system according to a first embodiment of the present disclosure.

FIG. 1B is a schematic cross-sectional view showing a cooling system according to a second embodiment of the present disclosure.

FIG. 2 is a schematic cross-sectional view showing a cooling system according to a third embodiment of the present disclosure.

FIG. 3 is a schematic cross-sectional view showing a cooling system according to a fourth embodiment of the present disclosure.

FIG. 4 is a schematic cross-sectional view showing a cooling system according to a fifth embodiment of the present disclosure.

FIG. 5A is a schematic cross-sectional view showing a cooling system according to a sixth embodiment of the present disclosure.

FIG. 5B is a schematic cross-sectional view showing a cooling system according to a seventh embodiment of the present disclosure.

FIG. 5C is a schematic cross-sectional view showing a cooling system according to an eighth embodiment of the present disclosure.

FIG. 5D is a schematic cross-sectional view showing a cooling system according to a ninth embodiment of the present disclosure.

FIG. 6A is a three-dimensional schematic diagram showing a cooling system according to a tenth embodiment of the present disclosure.

FIG. 6B is a schematic cross-sectional view showing the cooling system according to the tenth embodiment of the present disclosure.

FIG. 7 is a three-dimensional schematic diagram showing a cooling system according to an eleventh embodiment of the present disclosure.

FIG. 8 is a system architecture diagram showing a cooling system according to a twelfth embodiment of the present disclosure.

FIG. 9A is a cross-sectional view showing a cooling component of a cooling system according to a thirteenth embodiment of the present disclosure.

FIG. 9B is a cross-sectional view showing a cooling component of a cooling system according to a fourteenth embodiment of the present disclosure.

FIG. 10 is a schematic cross-sectional view showing a film coating process of a cooling system according to a fifteenth embodiment of the present disclosure.

### DETAILED DESCRIPTION

Various embodiments are described in detail below. However, the embodiments are merely used as examples for description and do not limit or reduce the protection scope of the present disclosure. In addition, some components are omitted in the drawings in the embodiments to clearly show the technical features of the present disclosure. Moreover, same labels in all drawings are used to represent same or similar components, the drawings of the present disclosure are merely examples for description and may not necessarily be drawn to scale, and all details may not necessarily be presented in the drawings.

The following uses an example in which a heterogeneous integrated semiconductor package structure serves as a to-be-cooled member for description, but the present disclosure is not limited thereto. Other similar semiconductor package members such as a silicon photonics package member or other advanced package members are also applicable to the present disclosure.

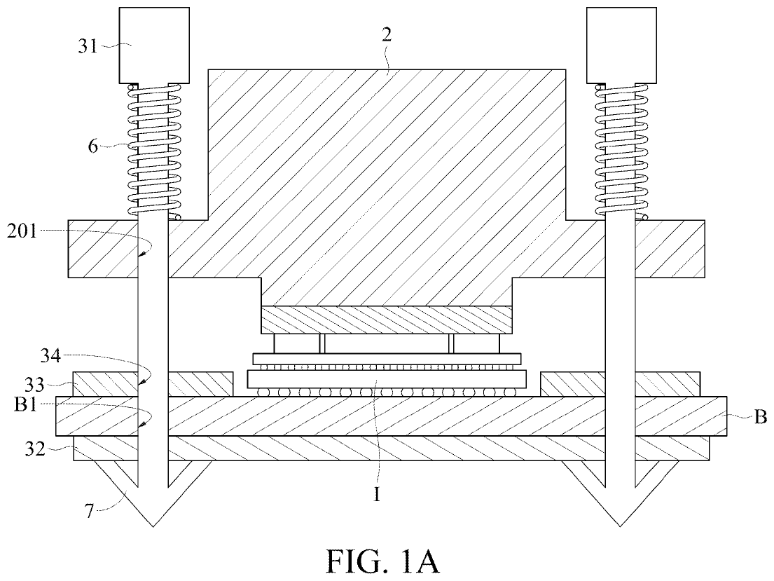

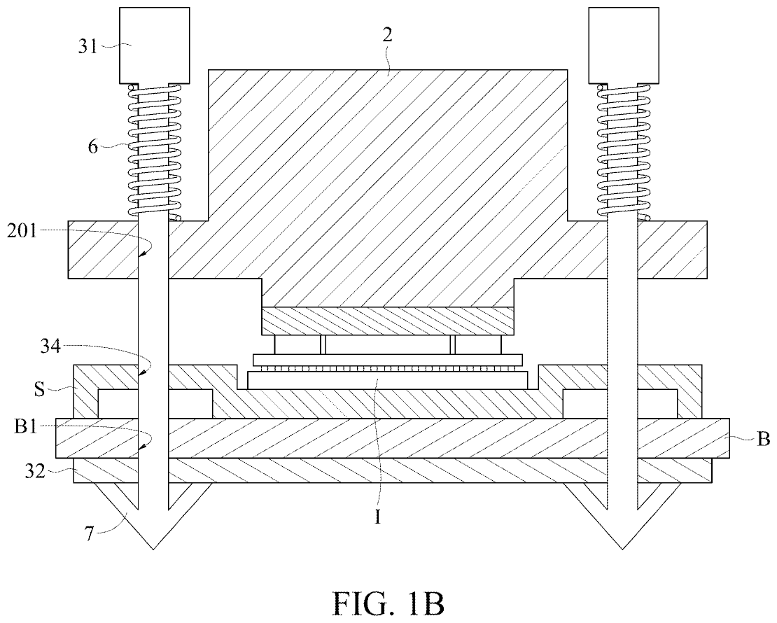

FIG. 1A is a schematic cross-sectional view showing a cooling system according to a first embodiment of the present disclosure. As shown in the figure, a heterogeneous integrated semiconductor package structure I is arranged on a circuit board B. The cooling system includes a cooling component 2, a thermally conductive fastener 31, and a heat dissipation plate 32. The cooling component 2 is arranged on the heterogeneous integrated semiconductor package structure I.

In some embodiments, the cooling component 2 may be a liquid cooling plate or an air cooling plate filled with a cooling fluid, or may be a vapor chamber, or may be other cooling plates with a heat conduction or dissipation effect. It should be particularly noted that, the cooling fluid may be a refrigerant, pure water, ethylene glycol, propylene glycol, or a combination thereof. If the cooling fluid is expected to be non-conductive, deionized water, an electronic fluoride solution, or other electronic engineering fluids may be employed. However, the cooling fluid is not limited to a liquid, and may alternatively be a low-temperature gas such as nitrogen, carbon dioxide, helium, or hydrogen.

The thermally conductive fastener 31 may be made of a metal material with a relatively desirable thermal conductivity, such as copper. One end of the thermally conductive fastener 31 has a compression spring 6 sleeved thereon, and another end is provided with a barb 7. The heat dissipation plate 32 is arranged on a side of the circuit board B opposite to the heterogeneous integrated semiconductor package structure I. In this embodiment, the heat dissipation plate is located on a back side of the circuit board B. Moreover, the heat dissipation plate 32 may be made of a metal material with a relatively desirable thermal conductivity, such as copper, to facilitate heat dissipation. In some embodiments, to avoid a short circuit of a circuit or an electronic component on the circuit board B caused by the heat dissipation plate 32, an insulating pad (not shown in the figure) may be further arranged between the circuit board B and the heat dissipation plate 32.

In addition, FIG. 1A further shows a stiffener 33, which is arranged on the circuit board B on the same side as the heterogeneous integrated semiconductor package structure I. In some embodiments, the stiffener 33 may be a commonly used stiffener or other metal members for stiffening the circuit board B. The stiffener 33 may be made of a metal material with a relatively desirable thermal conductivity, to facilitate heat dissipation. The cooling component 2 includes a plurality of perforations 201, preferably, four perforations 201, which may be arranged at four corners of the cooling component 2. The circuit board B includes a plurality of through holes B1. The stiffener 33 includes a plurality of openings 34. A quantity and positions of the through holes B1 and a quantity and positions of the openings 34 may correspond to those of the perforations 201 of the cooling component 2.

In addition, a quantity of the thermally conductive fasteners 31 is consistent with the quantity of the perforations 201 of the cooling component 2. Each of the thermally conductive fasteners 31 extends through one of the perforations 201 of the cooling component 2, one of the openings 34 of the stiffener 33, and one of the through holes B1 of the circuit board B. The barb 7 is fixed to a lower surface of the heat dissipation plate 32. The compression spring 6 is sandwiched between the thermally conductive fastener 31 and the cooling component 2, and applies a proper compression force to the cooling component 2, to ensure that a lower surface of the cooling component 2 is completely attached to an upper surface of the heterogeneous integrated semiconductor package structure I.

Based on the above, in the thermally conductive fastener 31 in this embodiment, the barb design is used, which facilitates assembly and disassembly, and the compression spring 6 may be replaced to adjust the compression force applied to the cooling component 2, so that the compression force may be flexibly adjusted. In addition, the thermally conductive fastener 31 has an excellent thermal conductivity, which may conduct heat of the cooling component 2 to the stiffener 33 and the heat dissipation plate 32, and the stiffener 33 and the heat dissipation plate 32 may facilitate heat dissipation, thereby improving heat dissipation efficiency.

FIG. 1B is a schematic cross-sectional view showing a cooling system according to a second embodiment of the present disclosure. A main difference between the second embodiment and the above embodiment lies in that a chip socket S is arranged on the circuit board B. In this case, the stiffener 33 in the above embodiment is replaced with the chip socket S. In this embodiment, similarly, the thermally conductive fastener 31 extends through the cooling component 2, the chip socket S, the circuit board B, and the heat dissipation plate 32, and the barb 7 of the thermally conductive fastener 31 is fixed to the lower surface of the heat dissipation plate 32.

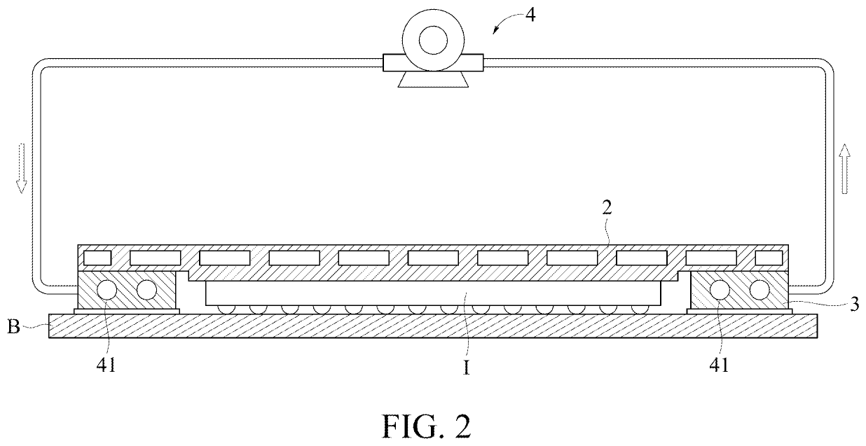

Referring to FIG. 2, FIG. 2 is a schematic cross-sectional view showing a cooling system according to a third embodiment of the present disclosure. In this embodiment, the cooling component 2 is a vapor chamber, which is in contact with a reinforcing frame 3. The vapor chamber has an excellent heat conduction capability, which can quickly spread heat to the surroundings from the semiconductor packaging structure with very concentrated heat density, thereby avoiding overheating of the semiconductor package structure. In some embodiments, the reinforcing frame 3 may be a commonly used stiffener or other metal components for stiffening the circuit board B. The reinforcing frame 3 may be made of a metal material with a relatively desirable thermal conductivity, such as copper.

In addition, FIG. 2 further shows a cooling fluid driving module 4, which may include a pump and a fluid delivery pipe. A cooling fluid passage 41 is arranged in the reinforcing frame 3, which is in communication with the cooling fluid driving module 4. The cooling fluid driving module 4 is adapted to supply a cooling fluid to the cooling fluid passage 41. Based on the above, in this embodiment, the cooling fluid passage 41 is provide inside the reinforcing frame 3 to circulate the cooling fluid. This embodiment also combines the reinforcing frame 3, the cooling fluid driving module 4, and the vapor chamber. The vapor chamber has good heat conduction characteristics, so it can transfer heat to the reinforcing frame 3 around it. The cooling fluid then carries away the heat, providing fast heat dissipation and saving space.

In some embodiments, the cooling fluid driving module 4 may further have a liquid storage tank (not shown in the figure) and a heat exchanger (not shown in the figure). The liquid storage tank may store a proper amount of cooling fluids, to ensure that the cooling fluid driving module 4 can continuously supply the cooling fluid to the reinforcing frame 3. The heat exchanger may be a fin heat exchanger with a fan, which may further dissipate heat of a circulating cooling fluid. In other embodiments, the heat exchanger may be a chiller, which may further regulate a temperature of the cooling fluid to a lower temperature.

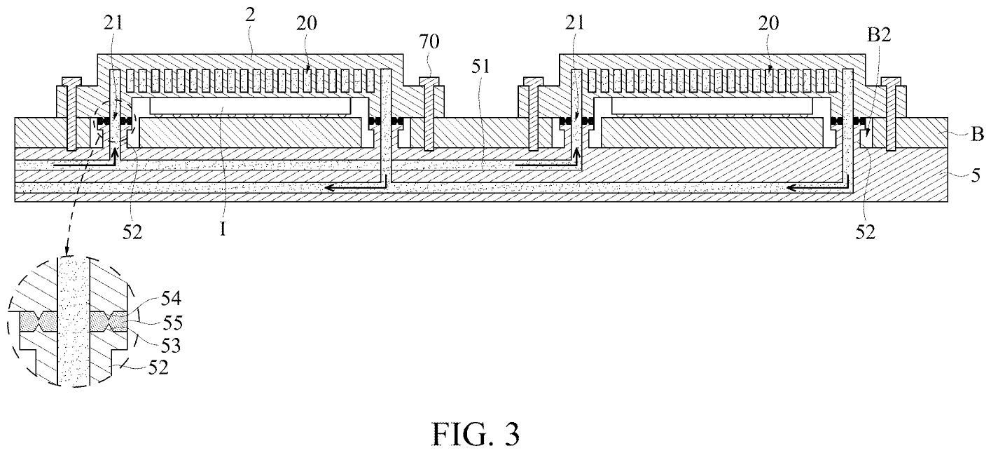

FIG. 3 is a schematic cross-sectional view showing a cooling system according to a fourth embodiment of the present disclosure. In the embodiment shown in the figure, the cooling system includes the cooling component 2 and a flow path component 5. The cooling component 2 is arranged on the heterogeneous integrated semiconductor package structure I, and the flow path component 5 is arranged on a side of the circuit board B opposite to the heterogeneous integrated semiconductor package structure I, that is, a back side of the circuit board B. In some embodiments, the cooling component 2 may be a cooling plate including an internal chamber 20 and a plurality of openings 21, and the flow path component 5 may be a guide back plate including a plurality of fluid channels 51 and a plurality of protrusions 52.

The circuit board B includes a plurality of through holes B2. The protrusions 52 of the flow path component 5 respectively extend through the through holes B2 and are bonded to the cooling component 2. In some embodiments, the bonding between the cooling component 2 and the flow path component 5 may be achieved through screw locking, as shown in FIG. 3. Further, a locking screw 70 may be caused to extend through the cooling component 2 and the circuit board B and be locked onto the flow path component 5. In addition, the fluid channels 51 of the flow path component 5 respectively extend to the protrusions 52, and are in communication with the internal chamber 20 of the cooling component 2 through the openings 21.

In other embodiments, the protrusions 52 of the flow path component 5 are not limited to extending through the through holes B2 on the circuit board B and being bonded to the cooling component 2. That is to say, when no through hole B2 is arranged on the circuit board B, the protrusions 52 may be bonded to the cooling component 2 along a side edge of the circuit board B (not shown in the figure). In other words, in other embodiments, a bonding position between the cooling component 2 and the flow path component 5 may be adjusted according to an actual requirement. For example, the bonding position may be at the side edge of the circuit board B or other proper positions.

In addition, in some embodiments, oxygen-free copper seal components 55 may be arranged at the coupling position between the flow path component 5 and the cooling component 2. A reason for using the seal members made of oxygen-free copper is that the copper material is soft, and has high toughness and excellent ductility. Moreover, each of the protrusions 52 includes a first pointed seal unit 53, which may be arranged based on a shape of the oxygen-free copper seal components 55, for example, may be arranged as an annular structure. Likewise, the cooling component 2 may include a plurality of second pointed seal units 54, which respectively surround the openings 21. A position, a size, and a shape of each of the second pointed seal units 54 may be consistent with that of the first pointed seal unit 53.

Based on the above, the first pointed seal units 53 and the second pointed seal units 54 are respectively pierced into two opposite sides of the oxygen-free copper seal components 55, so that the protrusions 52 are coupled to the cooling component 2 and form a seal.

Based on the above, in some embodiments of the present disclosure, the cooling component 2 can be supplied with cooling fluid through the fluid channels 51 of the flow path component 5, to further achieve forced circulation of the cooling fluid. In addition, in this embodiment, the flow path is arranged below the circuit board B, which not only saves space, but also simplifies the configuration of relevant components on the circuit board B, thereby facilitating disassembly or maintenance of electronic members on the circuit board B. Moreover, connection of the fluid flow path may be completed during assembly of the cooling component 2. This makes it easier to achieve fully automated assembly.

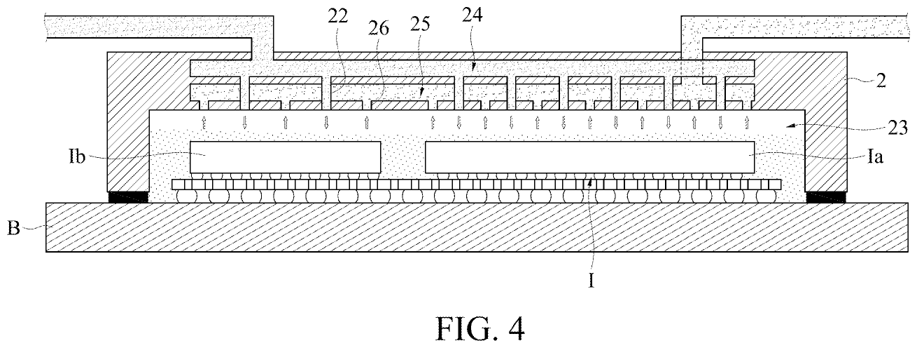

FIG. 4 is a schematic cross-sectional view showing a cooling system according to a fifth embodiment of the present disclosure. As shown in the figure, the heterogeneous integrated semiconductor package structure I includes a first heat-generating portion Ia and a second heat-generating portion Ib. Each may each be a chiplet. In this embodiment, a thermal design power (TDP) of the first heat-generating portion Ia is preset to be greater than a thermal design power of the second heat-generating portion Ib. That is to say, during respective operation of the two chiplets, a temperature of the first heat-generating portion Ia is higher than a temperature of the second heat-generating portion Ib. In this case, it will cause uneven temperature distribution in the entire packaging structure. In particular, a problem of thermal crosstalk occurs. This affects reliability of the semiconductor package structure.

As shown in FIG. 4, the cooling component 2 may include a plurality of fluid supply holes 22, which respectively correspond to the first heat-generating portion Ia and the second heat-generating portion Ib. In some embodiments, to resolve the above problem of uneven temperature distribution in the semiconductor package structure, a jet impingement technology may be employed, which is implemented by for example causing a flow rate of a cooling fluid sprayed onto the first heat-generating portion Ia through the fluid supply holes 22 to be higher than a flow rate of a cooling fluid sprayed onto the second heat-generating portion Ib through the fluid supply holes. The supply of the cooling fluid with a larger flow rate can carry more heat away compared with the supply of the cooling fluid with a smaller flow rate, thereby significantly reducing the temperature of the first heat-generating portion Ia and maintaining the temperatures of the first heat-generating portion Ia and the second heat-generating portion Ib as consistent as possible.

In a specific implementation, as shown in the figure, the cooling component 2 includes a main fluid chamber 23, a fluid supply chamber 24, a fluid recovery chamber 25, a plurality of fluid supply holes 22, and a plurality of fluid recovery holes 26. The fluid supply holes 22 are configured to be in communication with the main fluid chamber 23 and the fluid supply chamber 24. The fluid recovery holes 26 are configured to be in communication with the main fluid chamber 23 and the fluid recovery chamber 25. A configuration density of the fluid supply holes 22 corresponding to the first heat-generating portion Ia is greater than a configuration density of the fluid supply holes 22 corresponding to the second heat-generating portion Ib.

In other words, compared with the second heat-generating portion Ib, the first heat-generating portion Ia with a higher thermal design power may be correspondingly provided with more and denser jet impingement-based jet holes (the fluid supply holes 22), to improve heat dissipation efficiency. Specific arrangement of the fluid supply holes 22 may be determined based on a heat flux (HF). A relational expression of the HF is as follows: HF=TDP/surface area of a heat-generating portion.

For example, the heat flux (HF1) of the first heat-generating portion Ia is calculated as the thermal design power (TDP1) of the first heat-generating portion Ia divided by the surface area of an upper surface of the first heat-generating portion Ia. Similarly, the heat flux (HF2) of the second heat-generating portion Ib is calculated as the thermal design power (TDP2) of the second heat-generating portion Ib divided by the surface area of an upper surface of the second heat-generating portion Ib. When the heat flux (HF1) of the first heat-generating portion Ia is greater than the heat flux (HF2) of the second heat-generating portion Ib, the configuration density (ρ1) of the fluid supply holes Ps corresponding to the first heat-generating portion Ia should be greater than the configuration density (ρ2) of the fluid supply holes Ps corresponding to the second heat-generating portion Ib.

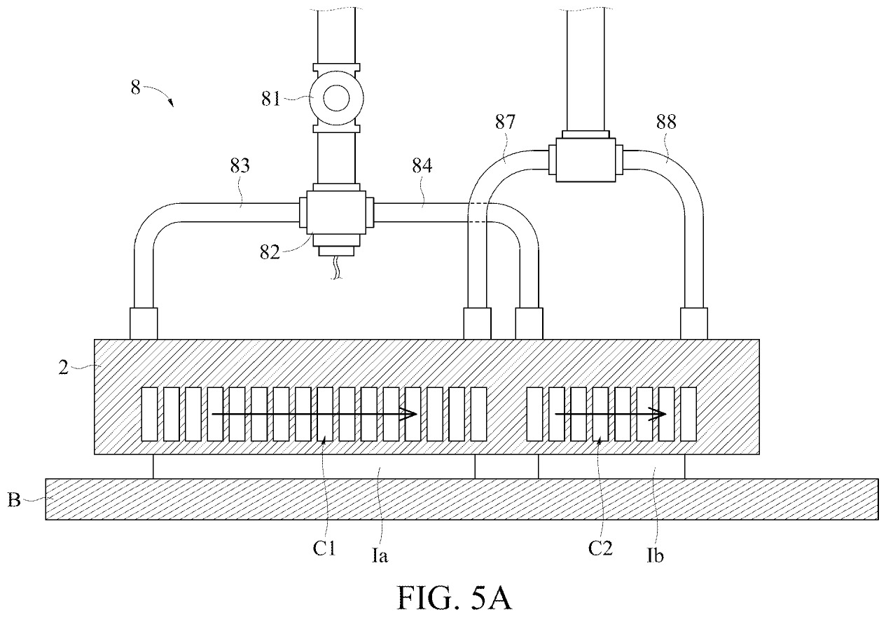

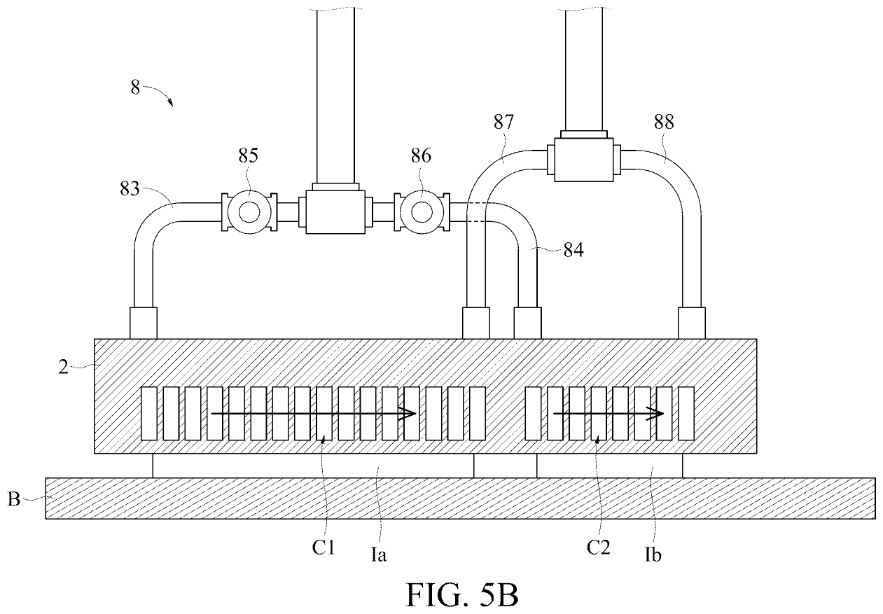

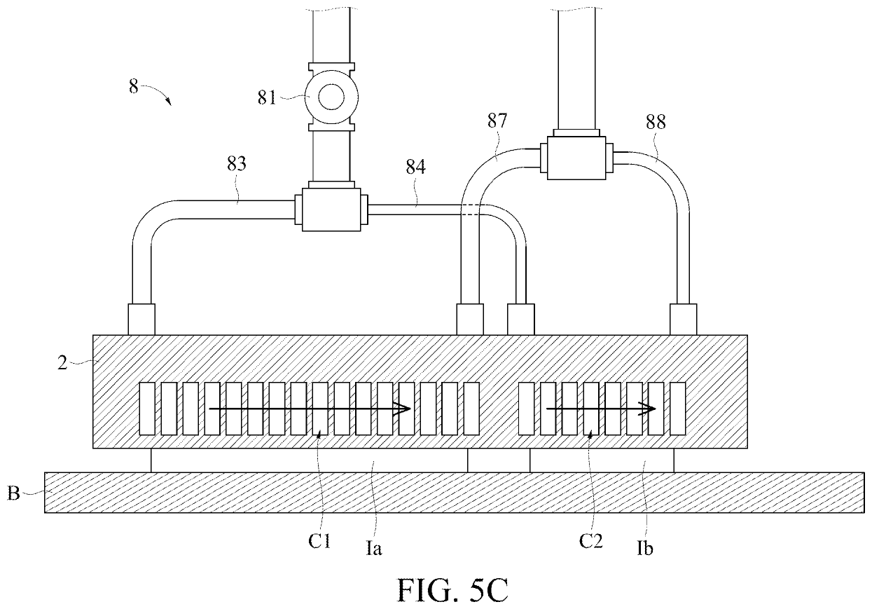

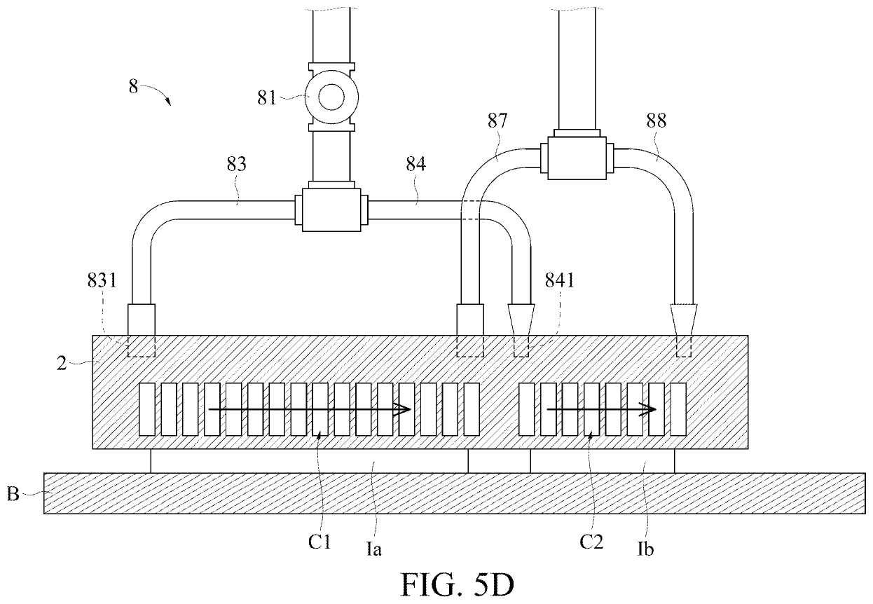

In other embodiments in which an enclosed cooling plate is used, thermal control may be performed for a plurality of chiplets with different thermal design powers. FIG. 5A is a schematic cross-sectional view showing a cooling system according to a sixth embodiment of the present disclosure. The cooling system show in the figure further includes a fluid supply module 8. The heterogeneous integrated semiconductor package structure I includes the first heat-generating portion Ia and the second heat-generating portion Ib. The thermal design power of the first heat-generating portion Ia is greater than the thermal design power of the second heat-generating portion Ib.

In addition, the cooling component 2 includes a first fluid chamber C1 and a second fluid chamber C2. The first fluid chamber C1 may correspond to the first heat-generating portion Ia, and the second fluid chamber C2 may correspond to the second heat-generating portion Ib. However, in some embodiments, the thermal control of the first heat-generating portion Ia and the second heat-generating portion Ib may be achieved by controlling the flow rates of respective cooling fluids in the first fluid chamber C1 and the second fluid chamber C2. That is to say, a flow rate of the cooling fluid supplied to the first fluid chamber C1 by the fluid supply module 8 may be caused to be greater than a flow rate of the cooling fluid supplied to the second fluid chamber C2 by the fluid supply module, to achieve the thermal control.

In the embodiment of FIG. 5A, the fluid supply module 8 includes a fluid supply pump 81, a fluid distribution valve 82, a first inlet pipe 83, a second inlet pipe 84, a first outlet pipe 87, and a second outlet pipe 88. Two ends of the first inlet pipe 83 are respectively in communication with the fluid distribution valve 82 and the first fluid chamber C1. Two ends of the second inlet pipe 84 are respectively in communication with the fluid distribution valve 82 and the second fluid chamber C2. One end of the first outlet pipe 87 is in communication with the first fluid chamber C1, and another end is in communication with a fluid storage tank (not shown in the figure). Similarly, one end of the second outlet pipe 88 is in communication with the second fluid chamber C2, and another end is in communication with a fluid storage groove (not shown in the figure). The fluid distribution valve 82 may be a proportional flow control valve, which is an apparatus that controls a flow rate of a fluid (including a liquid and a gas) through an electronic signal.

Specific operation in this embodiment is described as follows: The fluid supply pump 81 supplies the cooling fluid to the fluid distribution valve 82. The fluid distribution valve 82 distributes the cooling fluid to the first fluid chamber C1 and the second fluid chamber C2 based on a predetermined proportion. Cooling fluids in the first fluid chamber C1 and the second fluid chamber C2 after heat exchange may respectively flow out through the first outlet pipe 87 and the second outlet pipe 88. However, in this embodiment, since the thermal design power of the first heat-generating portion Ia is greater than the thermal design power of the second heat-generating portion Ib, the fluid distribution valve 82 distributes the cooling fluid based on a proportion such that a flow rate of the cooling fluid supplied to the first inlet pipe 83 is greater than a flow rate of the cooling fluid supplied to the second inlet pipe 84.

FIG. 5B is a schematic cross-sectional view showing a cooling system according to a seventh embodiment of the present disclosure. A main difference between this embodiment and the above embodiment lies in that the fluid supply pump 81 and the fluid distribution valve 82 in the above embodiment are replaced with a first fluid supply pump 85 and a second fluid supply pump 86. The first fluid supply pump 85 is specially configured to supply a cooling fluid to the first fluid chamber C1, and the second fluid supply pump 86 is specially configured to supply the cooling fluid to the second fluid chamber C2. Similarly, a flow rate of the cooling fluid supplied to the first fluid chamber C1 by the first fluid supply pump 85 is greater than a flow rate of the cooling fluid supplied to the second fluid chamber C2 by the second fluid supply pump 86. In some embodiments, the first fluid supply pump 85 and the second fluid supply pump 86 may be arranged as pumps with different volumetric flow rates or may be pumps with a switchable supply flow rate.

FIG. 5C is a schematic cross-sectional view showing a cooling system according to an eighth embodiment of the present disclosure. A main difference between this embodiment and the above embodiment lies in that, in this embodiment, a pipe diameter of the first inlet pipe 83 is different from a pipe diameter of the second inlet pipe 84, and that the flow rates of the cooling fluids entering the first fluid chamber C1 and the second fluid chamber C2 are controlled through the different pipe diameters of the inlet pipes.

Further, as shown FIG. 5C, the fluid supply module 8 includes the fluid supply pump 81, the first inlet pipe 83, the second inlet pipe 84, the first outlet pipe 87, and the second outlet pipe 88. Two ends of the first inlet pipe 83 are respectively in communication with the fluid supply pump 81 and the first fluid chamber C1. Two ends of the second inlet pipe 84 are respectively in communication with the fluid supply pump 81 and the second fluid chamber C2. One end of the first outlet pipe 87 is in communication with the first fluid chamber C1, and another end is in communication with a fluid storage tank (not shown in the figure). Similarly, one end of the second outlet pipe 88 is in communication with the second fluid chamber C2, and another end is in communication with a fluid storage groove (not shown in the figure).

Therefore, the fluid supply pump 81 may supply the cooling fluid to the first fluid chamber C1 and the second fluid chamber C2 respectively through the first inlet pipe 83 and the second inlet pipe 84, and the cooling fluids in the first fluid chamber C1 and the second fluid chamber C2 may flow out through the first outlet pipe 87 and the second outlet pipe 88. However, in this embodiment, pipe diameters of the first inlet pipe 83 and the first outlet pipe 87 are greater than pipe diameters of the second inlet pipe 84 and the second outlet pipe 88. In this case, the flow rate of the cooling fluid flowing into the first fluid chamber C1 is greater than the flow rate of the cooling fluid flowing into the second fluid chamber C2.

FIG. 5D is a schematic cross-sectional view showing a cooling system according to a ninth embodiment of the present disclosure. A main difference between this embodiment and the above embodiment lies in that, in this embodiment, an orifice diameter of an inlet hole 831 of the first fluid chamber C1 is different from an orifice diameter of an inlet hole 841 of the second fluid chamber C2, and that flow rates of the cooling fluids entering the first fluid chamber C1 and the second fluid chamber C2 are controlled through the different pore sizes of the inlet holes.

Further, the fluid supply module 8 includes the fluid supply pump 81, the first inlet pipe 83, the second inlet pipe 84, the first outlet pipe 87, and the second outlet pipe 88. Two ends of the first inlet pipe 83 are respectively in communication with the fluid supply pump 81 and the first fluid chamber C1. Two ends of the second inlet pipe 84 are respectively in communication with the fluid supply pump 81 and the second fluid chamber C2. One end of the first outlet pipe 87 is in communication with the first fluid chamber C1, and another end is in communication with a fluid storage tank (not shown in the figure). Similarly, one end of the second outlet pipe 88 is in communication with the second fluid chamber C2, and another end is in communication with a fluid storage groove (not shown in the figure).

Therefore, the fluid supply pump 81 may supply the cooling fluid to the first fluid chamber C1 and the second fluid chamber C2 respectively through the first inlet pipe 83 and the second inlet pipe 84, and the cooling fluids in the first fluid chamber C1 and the second fluid chamber C2 may flow out through the first outlet pipe 87 and the second outlet pipe 88. However, in this embodiment, the pore size of the inlet hole 831 of the first fluid chamber C1 is greater than the pore size of the inlet hole 841 of the second fluid chamber C2. In this case, the flow rate of the cooling fluid flowing into the first fluid chamber C1 is greater than the flow rate of the cooling fluid flowing into the second fluid chamber C2.

Based on the above, in the embodiments shown in FIG. 5A to FIG. 5D, the cooling component 2 may be equipped with a fluid chamber for each heat-generating portion on the heterogeneous integrated semiconductor package structure I, and the cooling system may provide a cooling fluid with a different flow rate for each fluid chamber. A magnitude of the flow rate is set based on a thermal design power of each heat-generating portion. A high thermal design power indicates that the heat-generating portion will generate a relatively high temperature. In this case, a cooling fluid with a relatively large flow rate may be supplied to a fluid chamber corresponding to the heat-generating portion, thereby maintaining the temperatures of the heterogeneous integrated semiconductor package structure I as consistent as possible, to avoid thermal crosstalk.

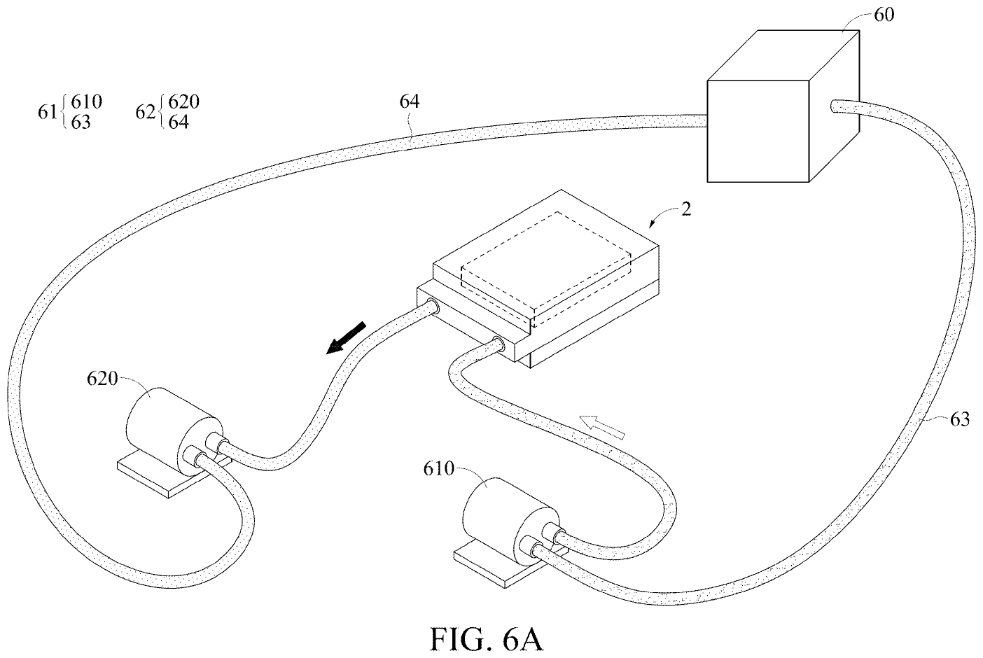

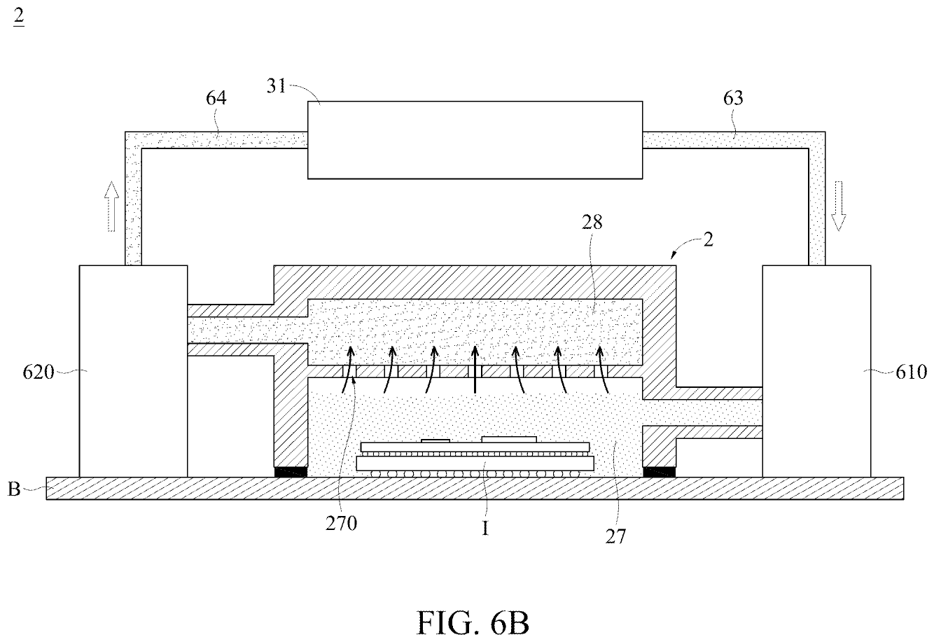

Referring to both FIG. 6A and FIG. 6B, FIG. 6A is a three-dimensional schematic diagram showing a cooling system according to a tenth embodiment of the present disclosure, and FIG. 6B is a schematic cross-sectional view showing the cooling system according to the tenth embodiment of the present disclosure. A fluid storage unit 60, a fluid supply module 61, and a fluid recovery module 62 are shown in FIG. 6A and FIG. 6B. The fluid storage unit 60 stores a cooling fluid. The fluid supply module 61 includes a liquid supply pump 610 and a fluid supply pipeline 63. The fluid recovery module 62 includes a gas recovery pump 620 and a fluid recovery pipeline 64. Two ends of each of the fluid supply pipeline 63 and the fluid recovery pipeline 64 are respectively in communication with the fluid storage unit 60 and the cooling component 2.

In addition, the liquid supply pump 610 is arranged on the fluid supply pipeline 63. The gas recovery pump 620 is arranged on the fluid recovery pipeline 64. The cooling system supplies the cooling fluid to the cooling component 2 through the liquid supply pump 610 and the fluid supply pipeline 63, and draws the evaporated cooling fluid from the cooling component 2 through the gas recovery pump 620 and the fluid recovery pipeline 64. In addition, as shown in FIG. 6B, the cooling component 2 includes a cooling chamber 27 and a recovery chamber 28, which are in communication with each other through a through hole 270.

Based on the above configuration, in case of a high performance computing (HPC) requirement, the temperature of the heterogeneous integrated semiconductor package structure I may rise to a temperature that is high enough to evaporate the cooling fluid and thus result in coexistence of a gaseous phase and a liquid phase, for example, a two-phase immersion cooling solution. In this case, after the liquid cooling fluid located in the cooling chamber 27 is heated and evaporated, the gaseous cooling fluid flows into the recovery chamber 28 through the through hole 270. However, the gas recovery pump 620 in this embodiment can draw the gaseous cooling fluid from the recovery chamber 28.

Overall, in this embodiment, through the liquid supply pump 610 and the fluid supply pipeline 63, the cooling fluid can be continuously supplied to the cooling component 2, and through the gas recovery pump 620 and the fluid recovery pipeline 64, the evaporated cooling fluid can be draw from the cooling component 2. In this way, forced circulation of two-phase cooling fluids can be achieved, thereby maintaining excellent heat dissipation efficiency. In addition, in other embodiments, a condenser or another heat exchanger (not shown in the figure) may be further arranged on the fluid recovery pipeline 64, which may be a fin heat exchanger with a fan. The heat exchanger can further dissipate heat from the circulating gaseous cooling fluid so that the gaseous cooling fluid condenses into a liquid cooling fluid.

Moreover, after the cooling component 2 has been in operation for an extended period, it may experience narrowed or even blocked flow channels or holes due to various factors such as incomplete debris removal after processing, impurity precipitation from the component itself, contamination in the cooling fluid, or microbial activity in the microchannels or fluid. This blockage would inevitably lead to overheating of the semiconductor packaging structure, potentially causing malfunctions or even irreversible damage.

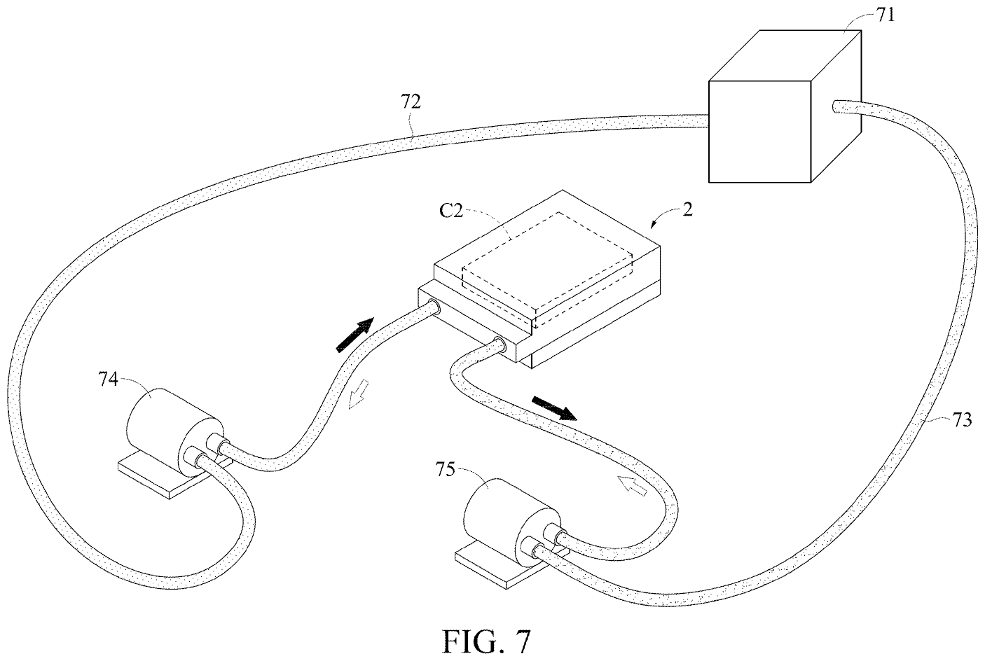

To resolve the above problem, an embodiment is provided below. FIG. 7 is a three-dimensional schematic diagram showing a cooling system according to an eleventh embodiment of the present disclosure. The embodiment shown in FIG. 7 includes the cooling component 2, a fluid storage unit 71, a fluid supply pipeline 72, a fluid recovery pipeline 73, a first fluid pump 74, and a second fluid pump 75. Further, the fluid storage unit 71 stores a cooling fluid. Two ends of the fluid supply pipeline 72 are respectively in communication with the fluid storage unit 71 and the cooling component 2. Two ends of the fluid recovery pipeline 73 are respectively in communication with the fluid storage unit 71 and the cooling component 2. The first fluid pump 74 is arranged on the fluid supply pipeline 72. The second fluid pump 75 is arranged on the fluid recovery pipeline 73. The cooling system may supply the cooling fluid to the cooling component 2 by using the first fluid pump 74 through the fluid supply pipeline 72, or may supply the cooling fluid to the cooling component 2 by using the second fluid pump 75 through the fluid recovery pipeline 73.

Specifically, during normal operation of the system, the second fluid pump 75 is deactivated. The cooling fluid is supplied to the cooling component 2 by the first fluid pump 74 through the fluid supply pipeline 72, and the cooling fluid is forcibly circulated for heat dissipation. The cooling fluid then flows back through the fluid recovery pipeline 73 to the fluid storage unit 71. Alternatively, when there is a need to flush the internal components of the cooling component 2, such as flushing internal channels or holes, the first fluid pump 74 can be deactivated, and the second fluid pump 75 is activated. In other words, the cooling fluid is supplied to the cooling component 2 by the second fluid pump 75 through the fluid recovery pipeline 73, and it flows back to the fluid storage unit 71 through the fluid supply pipeline 72.

Accordingly, the second fluid pump 75 will generate a reverse flushing that is opposite to the flow direction of the cooling fluid that is always running. This can effectively flush out foreign objects or impurities in the cooling component 2 or the pipeline. In other embodiments, a filter can also be configured in the fluid supply pipeline 72 or the fluid recovery pipeline 73 to filter out the flushed foreign objects or impurities.

In addition, in other embodiments, the first fluid pump 74 and the second fluid pump 75 may be bidirectional hydraulic pumps, providing the ability to switch the flow direction. In other words, during normal operation, the first fluid pump 74 and the second fluid pump 75 are both activated, and drive fluids to flow in the same direction, for example, in a counterclockwise direction shown in FIG. 7. When there is a need to flush the internal components of the cooling component 2, the first fluid pump 74 and the second fluid pump 75 are activated, but the flow direction is switched so that they drive the cooling fluid to flow in the opposite direction, for example, in a clockwise direction as shown in FIG. 7. In addition, in an embodiment in which the bidirectional pump is used, only one bidirectional pump may be arranged.

The operation monitoring of existing liquid cooling systems mostly adopts a separated approach, where the liquid cooling system and the computing system (such as a server) are separate systems with no information sharing between them. In other words, functions such as liquid temperature sensing, flow monitoring and distribution, cooling fluid pressure drop sensing, and real-time control of fluid-driven pumps in the liquid cooling system operate independently without real-time communication with the computing system (such as a server). Therefore, if there is an abnormal situation in the computing system (such as a server), the liquid cooling system cannot perceive it immediately and cannot respond promptly. Similarly, if there is an abnormal situation in the liquid cooling system, the computing system cannot perceive it immediately and cannot respond promptly.

Additionally, the existing liquid cooling system operates independently from the computing system (such as a server). In the existing cooling system, related sensors cannot be integrated into the computing system, leading to complex and messy sensor wiring, causing maintenance challenges, and resulting in higher costs.

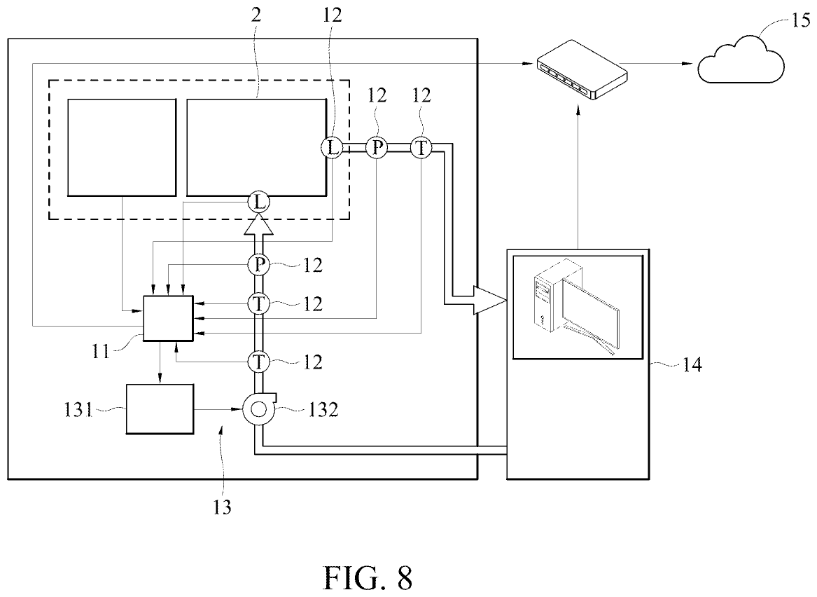

To resolve the above problem, an embodiment shown in FIG. 8 provides a solution. FIG. 8 is a system architecture diagram showing a cooling system according to a twelfth embodiment of the present disclosure. The cooling system in this embodiment further includes a controller 11, a plurality of sensors 12, a fluid driving unit 13, and a cooling distribution unit (CDU) 14. The controller 11 may be a microprocessor, a system on chip (SOC), a microcontroller, a field programmable gate array (FPGA), an application specific integrated circuit (ASIC) on a server mainboard or other controllers or processors on the mainboard. In a specific embodiment, a baseboard management controller (BMC) may be used.

In some embodiments, the sensors 12 may include, but are not limited to, leakage sensors, flow meters, pressure sensors, and fluid temperature sensors, among various sensors that monitor the condition of the cooling fluid. I. In some embodiments, the fluid driving unit 13 is adapted to supply a cooling fluid to the cooling component 2. The fluid driving unit 13 may include a driving circuit 131 and a pump 132. The driving circuit 131 is configured to control start, stop, and an operating status of the pump 132.

Further, the cooling distribution unit 14 is responsible for uniformly distributing the cooling fluid throughout the entire system, which includes but is not limited to a fluid storage tank, a heat sink, a heat exchanger, and a filter. As shown in FIG. 8, the controller 11 is electrically connected to the sensors 12 and the fluid driving unit 13. That is to say, the controller 11 may control the fluid driving unit 13 to supply the cooling fluid to the cooling component 2 based on the sensing results of the sensors 12.

For example, when the sensors 12 detect an abnormality, for example, a leakage of the cooling fluid, the controller 11 can not only control the fluid driving unit 13 to stop supplying the cooling fluid, but can also synchronously control the server system to execute a necessary protective measure, such as shutting down. On the other hand, if there is an abnormality in the server system, such as high processor temperature, the controller 11 may control the fluid driving unit 13 to increase the supply flow rate of the cooling fluid or reduce a temperature of the cooling fluid. For another example, when the server system shuts down, the controller 11 may autonomously control the entire cooling system to stop operating.

Put more simply, the controller 11 on the mainboard may coordinate operation between the cooling system and the server system, to achieve real-time monitoring of temperature, flow rate, pressure, leakage, and other conditions at the board level. It can promptly control the temperature, flow rate, and pressure of the cooling fluid based on the sensing results, allowing the system to maintain optimal performance and avoid severe failures. Further, the controller 11 on the mainboard may control, based on an operating status of the server system, the cooling system to perform corresponding operation such as start, shutdown, increasing the flow rate of the cooling fluid, increasing the temperature of the cooling fluid, reducing the flow rate of the cooling fluid, or reducing the temperature of the cooling fluid.

In addition, since the sensors 12 and electronic components of the server are all mounted to a same circuit board, the wiring cost of sensors may be reduced, along with a decrease in the complexity of sensor wiring. Moreover, remote control may be further implemented for the cooling system in this embodiment. For example, the controller 11 and the cooling distribution unit 14 are connected to a remote apparatus 15, and the entire cooling system and the server system may be remotely managed and monitored through the remote apparatus 15. When an abnormality occurs in the cooling system or the server system, the controller 11 reports the abnormality to the remote apparatus 15 in real time and take immediate actions.

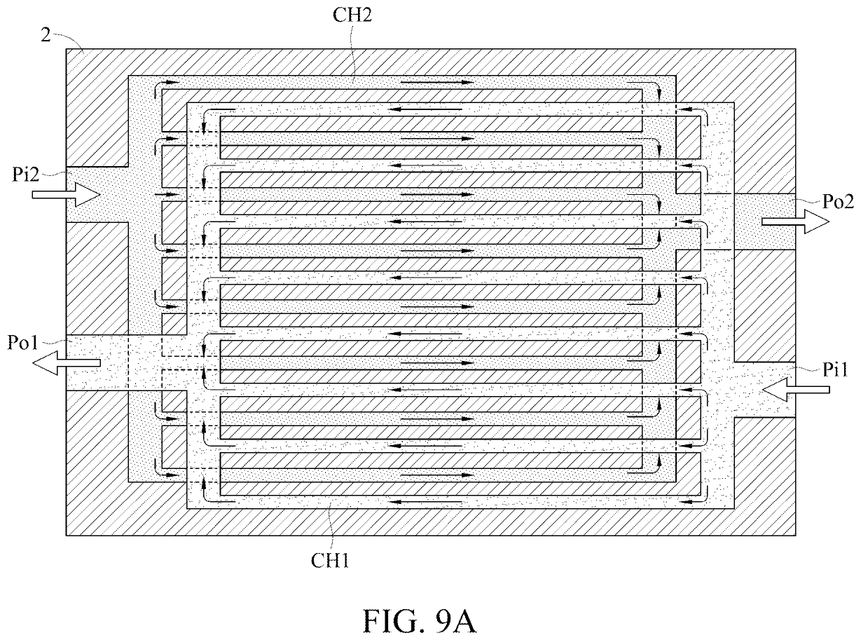

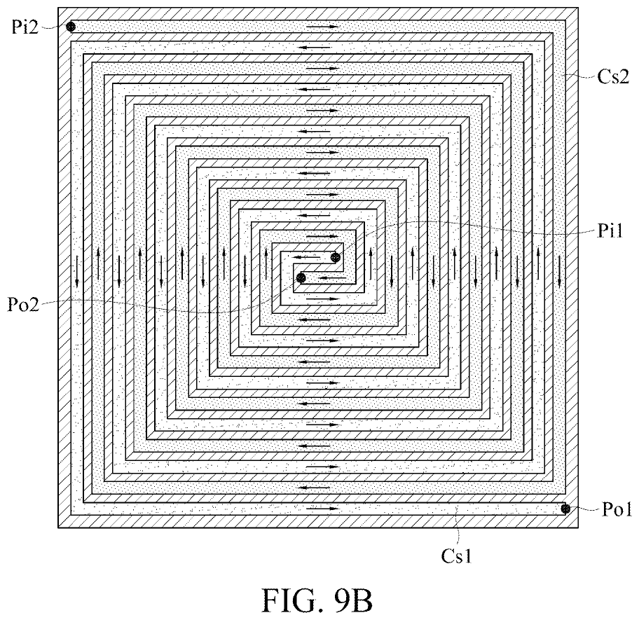

Referring to both FIG. 9A and FIG. 9B, FIG. 9A is a cross-sectional view showing a cooling component of a cooling system according to a thirteenth embodiment of the present disclosure, and FIG. 9B is a cross-sectional view showing a cooling component of a cooling system according to a fourteenth embodiment of the present disclosure. A conventional liquid cooling system cools electronic components by using a cold plate, and a flow channel is arranged in the cold plate, to increase a contact surface area between a cooling fluid and the cold plate, thereby improving cooling efficiency. However, existing flow channels are usually designed in a configuration of parallel flow channels, and cooling fluid of adjacent flow channels flow in a same flowing direction. While this design increases heat dissipation efficiency, it often results in uneven temperature distribution in the semiconductor packaging structure. For example, the region near the inlet may have a lower temperature, while the region near the outlet may have a higher temperature. To address this issue, the embodiments shown in FIGS. 9A and 9B introduce a novel flow channel design for the cooling component 2. This design not only significantly improves heat exchange efficiency but also ensures a uniform temperature distribution across the cooling component 2.

Refer to FIG. 9A first. The cooling component 2 includes a first inlet Pi1, a first outlet Po1, a second inlet Pi2, a second outlet Po2, a plurality of first fluid channels CH1, and a plurality of second fluid channels CH2. The first inlet Pi and the first outlet Po1 are respectively arranged on opposite sides of the cooling component 2, the second inlet Pi2 and the first outlet Po1 are arranged on a same side of the cooling component 2, and the second outlet Po2 and the first inlet Pi1 are arranged on a same side of the cooling component 2. Further, two ends of the first fluid channels CH1 are respectively in communication with the first inlet Pi1 and the first outlet Po1, and two ends of the second fluid channels CH2 are respectively in communication with the second inlet Pi2 and the second outlet Po2. In addition, the first fluid channels CH1 and the second fluid channels CH2 are arranged to be spaced apart from each other in the cooling component 2 in a substantially parallel and staggered manner.

Based on the above configuration, the flow directions of the cooling fluid inside the adjacent first fluid channels CH1 and second fluid channels CH2 can be made to be opposite to each other. Since the cooling fluid at the first inlet Pi1 and second inlet Pi2 has a lower temperature, and as the cooling fluid flows along the channels, it continuously exchanges heat with the body of the cooling component 2. This results in the cooling fluid reaching the highest temperature at the first outlet Po1 and second outlet Po2, which correspondingly have the first inlet Pi1 and second inlet Pi2 located, where the fluid temperature is lower. Therefore, through the configuration of the embodiment described above, the temperature at various locations within the cooling component 2 can be made roughly consistent, enhancing the uniformity of the surface temperature distribution of the semiconductor packaging structure.

In addition, in the embodiment shown in FIG. 9B, the cooling component 2 includes the first inlet Pi1, the first outlet Po1, the second inlet Pi2, the second outlet Po2, a first spiral flow channel CS1, and a second spiral flow channel CS2. The first inlet Pi1 and the first outlet Po1 are respectively located at opposite ends of the first spiral flow channel CS1. The second inlet Pi2 and the second outlet Po2 are respectively located at opposite ends of the second spiral flow channel CS2. The first inlet Pi1 and the second outlet Po2 are arranged approximately at a center of the cooling component 2. The first outlet Po1 and the second inlet Pi2 are arranged adjacent to two opposite corners of the cooling component 2, and are opposite to each other at a distance. Furthermore, the second spiral flow channel CS2 spirally surrounds the first spiral flow channel CS1 between the annular flow channels, and the flow direction of the cooling fluid inside the adjacent first spiral flow channel CS1 and second spiral flow channel CS2 is opposite to each other.

Accordingly, in some embodiments, the configuration of the cooling component 2 is not limited to a parallel flow channels and can also adopt a spiral flow channel configuration, achieving a similarly uniform temperature distribution. Moreover, in other embodiments, the design of the flow channels can also adopt different geometric shapes, and the number of inlets and outlets for the cooling fluid is not limited to two, with more inlets and outlets providing better heat dissipation efficiency.

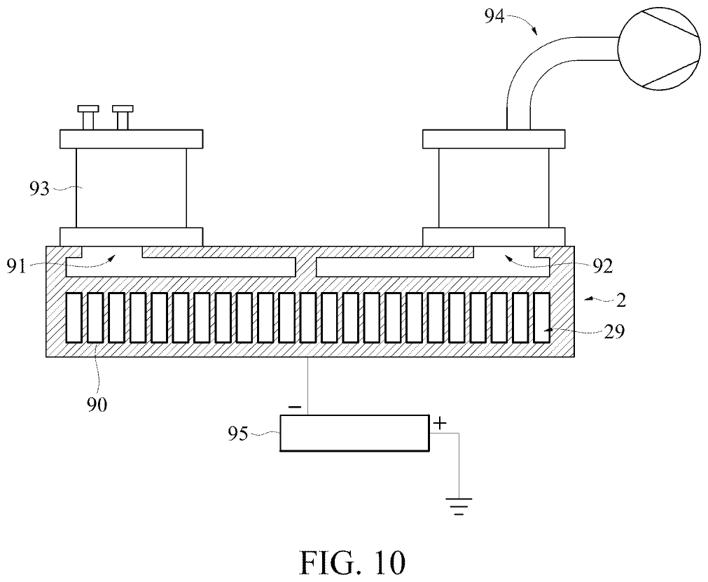

FIG. 10 is a schematic sectional view showing a film coating process of a cooling system according to a fifteenth embodiment of the present disclosure. Due to a high thermal conductivity of copper, most existing liquid cold plates (cooling component 2) are made of copper. However, flow channels in the existing copper liquid cooling plate are usually made in a mechanical processing manner such as die casting, milling, or machining, which results in a rough surface finish and high friction coefficient, leading to significant pressure drops when the cooling fluid flows through. To overcome the problem, the existing technology often increases fluid pressure, such as through the high-speed rotation of pumps. However, this approach not only increases power consumption costs but also raises the risk of cooling fluid leakage. Therefore, electroplating processes are commonly used to apply a nickel coating on the surface of the channels to prevent copper oxidation. However, nickel has a much lower thermal conductivity (97.5 W/mK) compared to copper (398 W/mK), which, in turn, reduces the efficiency of the cold plate (cooling component 2).

To address the aforementioned issues, a new coating method is provided for the cooling fluid channels inside the cooling component 2, as shown in the embodiment in FIG. 10. The coating has a high thermal conductivity (approximately 400 to 1000 W/mK), even higher than that of copper in the cooling component 2, so it does not affect the heat exchange and cooling efficiency. Moreover, this coating significantly reduces the surface roughness of the channels, effectively suppressing the pressure drop of the cooling fluid. Additionally, due to the high density of the coating on the channel surfaces, microbial growth is inhibited, and the likelihood of foreign particle adhesion is reduced, thereby minimizing the risk of blockage and significantly extending the lifespan.

The hardware configuration and related steps required for the coating process in the 15th embodiment are explained below. Refer to FIG. 10 together. As shown in FIG. 10, the cooling component 2 includes an internal flow channel 29, a fluid inlet 91, and a fluid outlet 92. Two ends of the internal flow channel 29 are respectively in communication with the fluid inlet 91 and the fluid outlet 92. Moreover, a precursor gas supply apparatus 93 is connected to the fluid inlet 91. A negative pressure generation apparatus 94 is connected to the fluid outlet 92. A power supply apparatus 95 is electrically connected to the cooling component 2, with a negative electrode thereof being connected to the cooling component 2 and a positive electrode thereof being grounded.

In some embodiments, the negative pressure generation apparatus 94 first vacuums the cooling component 2, and then the precursor gas supply apparatus 93 supplies a precursor gas to the cooling component 2, and controls a flow rate of the precursor gas, to maintain a vacuum degree of the cooling component 2 to be in a range of 10⁻¹ torrs to 10⁻⁴ torrs. The precursor gas may include but is not limited to alkane, alkyne, silane, and tetraethoxysilane (TEOS). Then, the power supply apparatus 95 is activated. In this case, an inner surface of the flow channel 29 of the cooling component 2 generate plasma, which deposits to form a diamond-like film 90.

The following provides process parameters of an embodiment. The power supply apparatus 95 supplies a pulsed direct current (pulsed DC) with a voltage in a range of 350 volts to 1000 volts. A pulse duration of the pulsed DC may be in a range of 5 μs to 35 μs, and a pulse rate may be 21 KHz. In addition, a supply flow rate of the precursor gas supply apparatus 93 may be in a range of 2 sccm to 7 sccm.

In other embodiments, before the precursor gas enters the flow channel 29 of the cooling component 2, an argon gas (Ar) may be introduced first for a Plasma Cleaning step to remove organic contaminants from the surface of the flow channel 29. After the Plasma Cleaning step and before the precursor gas enters the flow channel 29 of the cooling component 2, a silane gas may be introduced to pre-coat the surface with an amorphous silicon thin film, thereby increasing the adhesion of the subsequent diamond-like film 90.

Overall, the diamond-like film 90 in the above embodiment has at least the following advantages: The diamond-like film 90 is highly dense, with a smooth surface and a low friction coefficient, which can effectively suppress pressure drop. The diamond-like film 90 has a high thermal conductivity, which can improve cooling performance. The diamond-like film 90 exhibits high hardness, which can resist the high-speed impact of nanoparticles if nanoparticles are added to the cooling fluid, such as using nanofluid cooling technology, and reduce the wear of the inner wall. The diamond-like film 90 has corrosion resistance, with a surface roughness smaller than the size of bacteria, which can prevent microorganisms from attaching or breeding. The diamond-like film 90 employs vacuum chemical vapor deposition, eliminating issues related to waste liquid discharge and contributing to environmental conservation.

The above embodiments are merely examples for the purpose of illustration, and the scope claimed in the instant disclosure should be based on the claims, and is not limited to the above embodiments.

What is claimed is:

1. A cooling system for a heterogeneous integrated semiconductor package structure, wherein the heterogeneous integrated semiconductor package structure is arranged on a circuit board, and the cooling system comprises a cooling component arranged on the heterogeneous integrated semiconductor package structure.

2. The cooling system according to claim 1, further comprising a thermally conductive fastener and a heat dissipation plate, wherein the heat dissipation plate is arranged on a side of the circuit board opposite to the heterogeneous integrated semiconductor package structure, and the thermally conductive fastener is configured to be coupled to the cooling component and the heat dissipation plate.

3. The cooling system according to claim 2, further comprising a stiffener arranged on the circuit board, wherein the thermally conductive fastener is configured to be coupled to the cooling component, the stiffener, and the heat dissipation plate.

4. The cooling system according to claim 1, further comprising a reinforcing frame, wherein the reinforcing frame is arranged on the circuit board and is in contact with the cooling component.

5. The cooling system according to claim 4, wherein the cooling component comprises a vapor chamber.

6. The cooling system according to claim 5, further comprising a cooling fluid driving module, wherein the reinforcing frame comprises a cooling fluid passage in communication with the cooling fluid driving module, and the cooling fluid driving module is adapted to supply a cooling fluid to the cooling fluid passage.

7. The cooling system according to claim 1, further comprising a flow path component arranged on a side of the circuit board opposite to the heterogeneous integrated semiconductor package structure, wherein the flow path component is coupled to the cooling component, and comprises a plurality of fluid channels, the cooling component comprises an internal chamber, and the fluid channels are in communication with the internal chamber.

8. The cooling system according to claim 7, further comprising a plurality of oxygen-free copper seal components arranged at coupling positions between the flow path component and the cooling component.

9. The cooling system according to claim 1, wherein the heterogeneous integrated semiconductor package structure comprises a first heat-generating portion and a second heat-generating portion, a thermal design power (TDP) of the first heat-generating portion is greater than a thermal design power of the second heat-generating portion, the cooling component comprises a plurality of fluid supply holes corresponding to the heterogeneous integrated semiconductor package structure, and a flow rate of a cooling fluid sprayed onto the first heat-generating portion through the fluid supply holes is greater than a flow rate of a cooling fluid sprayed onto the second heat-generating portion through the fluid supply holes.

10. The cooling system according to claim 9, wherein the cooling component further comprises a main fluid chamber, a fluid supply chamber, a fluid recovery chamber, and a plurality of fluid recovery holes, the fluid supply holes are configured to be in communication with the main fluid chamber and the fluid supply chamber, the fluid recovery holes are configured to be in communication with the main fluid chamber and the fluid recovery chamber, and a configuration density of the fluid supply holes corresponding to the first heat-generating portion is greater than a configuration density of the fluid supply holes corresponding to the second heat-generating portion.

11. The cooling system according to claim 1, further comprising a fluid supply module, wherein the heterogeneous integrated semiconductor package structure comprises a first heat-generating portion and a second heat-generating portion, a thermal design power of the first heat-generating portion is greater than a thermal design power of the second heat-generating portion, the cooling component comprises a first fluid chamber and a second fluid chamber, the first fluid chamber corresponds to the first heat-generating portion, the second fluid chamber corresponds to the second heat-generating portion, the fluid supply module is adapted to supply a cooling fluid to the first fluid chamber and the second fluid chamber, and a flow rate of the cooling fluid supplied to the first fluid chamber by the fluid supply module is greater than a flow rate of the cooling fluid supplied to the second fluid chamber.

12. The cooling system according to claim 11, wherein the fluid supply module comprises a fluid supply pump, a fluid distribution valve, a first inlet pipe, and a second inlet pipe; two ends of the first inlet pipe are respectively connected to the fluid distribution valve and the first fluid chamber, two ends of the second inlet pipe are respectively connected to the fluid distribution valve and the second fluid chamber; the fluid supply pump is adapted to supply the cooling fluid to the fluid distribution valve, and the fluid distribution valve is configured to control the cooling fluid such that a flow rate of the cooling fluid supplied to the first inlet pipe to be greater than a flow rate of the cooling fluid supplied to the second inlet pipe.

13. The cooling system according to claim 11, wherein the fluid supply module comprises a first fluid supply pump and a second fluid supply pump; the first fluid supply pump is adapted to supply the cooling fluid to the first fluid chamber, the second fluid supply pump is adapted to supply the cooling fluid to the second fluid chamber, and a flow rate of the cooling fluid supplied to the first fluid chamber by the first fluid supply pump is greater than a flow rate of the cooling fluid supplied to the second fluid chamber by the second fluid supply pump.

14. The cooling system according to claim 11, wherein the fluid supply module comprises a fluid supply pump, a first inlet pipe, and a second inlet pipe; two ends of the first inlet pipe are respectively connected to the fluid supply pump and the first fluid chamber, two ends of the second inlet pipe are respectively connected the fluid supply pump and the second fluid chamber; the fluid supply pump is adapted to supply the cooling fluid to the first fluid chamber and the second fluid chamber respectively through the first inlet pipe and the second inlet pipe; and a pipe diameter of the first inlet pipe is greater than a pipe diameter of the second inlet pipe.

15. The cooling system according to claim 11, wherein the fluid supply module comprises a fluid supply pump, a first inlet pipe, and a second inlet pipe; two ends of the first inlet pipe are respectively connected to the fluid supply pump and an inlet hole of the first fluid chamber, two ends of the second inlet pipe are respectively connected to the fluid supply pump and an inlet hole of the second fluid chamber; the fluid supply pump is adapted to supply the cooling fluid to the first fluid chamber and the second fluid chamber respectively through the first inlet pipe and the second inlet pipe; and an orifice diameter of the inlet hole of the first fluid chamber is greater than an orifice diameter of the inlet hole of the second fluid chamber.

16. The cooling system according to claim 1, further comprising a fluid supply module and a fluid recovery module, wherein the cooling component comprises a cooling chamber and a recovery chamber, the cooling chamber and the recovery chamber are in communication with each other, the fluid supply module is in communication with the cooling chamber and is adapted to supply a cooling fluid to the cooling chamber, the fluid recovery module is in communication with the recovery chamber, and comprises a gas recovery pump, and the gas recovery pump is adapted to draw the evaporated cooling fluid from the recovery chamber.

17. The cooling system according to claim 1, further comprising a fluid storage unit, a fluid supply pipeline, a fluid recovery pipeline, a first fluid pump, and a second fluid pump; wherein the cooling component comprises a hollow chamber; the fluid storage unit stores a cooling fluid, two ends of each of the fluid supply pipeline and the fluid recovery pipeline are respectively connected to the fluid storage unit and the hollow chamber of the cooling component, the first fluid pump is arranged on the fluid supply pipeline, the second fluid pump is arranged on the fluid recovery pipeline, and the cooling fluid is supplied to the cooling component by the first fluid pump through the fluid supply pipeline, or the cooling fluid is supplied to the cooling component by the second fluid pump through the fluid recovery pipeline.

18. The cooling system according to claim 1, further comprising a controller, a sensor, and a fluid driving unit; wherein the fluid driving unit is adapted to supply a cooling fluid to the cooling component, and the controller is arranged on the circuit board, is electrically connected to the sensor and the fluid driving unit, and is adapted to control the fluid driving unit to supply the cooling fluid to the cooling component based on a sensing result of the sensor.

19. The cooling system according to claim 1, wherein the cooling component comprises a plurality of first fluid channels and a plurality of second fluid channels, the first fluid channels and the second fluid channels are arranged to be spaced apart from each other in the cooling component in a substantially parallel and staggered manner, and flowing directions of cooling fluids in the first fluid channel and the second fluid channel adjacent to each other are opposite to each other.

20. The cooling system according to claim 1, wherein the cooling component comprises a flow channel, and an inner surface of the flow channel is coated with a diamond-like film.
